(19) United States
(12) Patent Application Publication
(10) Pub. No.: US 2010/0302888 A1
(43) Pub. Date: Dec. 2, 2010

(54) DYNAMIC RANDOM ACCESS MEMORY DEVICE AND INSPECTION METHOD THEREOF

(75) Inventors: Yuki MORI, Kokubunji-shi (JP); Kensuke OKONOGI, Chuo-ku (JP); Shuichi TSUKADA, Chuo-ku (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 12/788,428

(22) Filed: May 27, 2010

(30) Foreign Application Priority Data
Jun. 2, 2009 (JP) 2009-132862

(51) Int. Cl. G11C 29/00

(52) U.S. Cl. 365/201

(57) ABSTRACT

A memory cell potentially including a retention fault attributable to a random change over time of data retention capability is screened by applying a bias to a gate electrode such that holes are accumulated on an interface of a substrate that is a component of a memory cell transistor on the side of the gate electrode and, after applying the bias, performing a pause-refresh test for inspecting the data retention capability of the memory cell.

This application is based upon and claims the benefit of priority from Japanese patent application No. 2009-132862, filed on Jun. 2, 2009, the disclosure of which is incorporated herein in its entirety by reference.

### BACKGROUND OF THE INVENTION

1. Field of the Invention

The present invention relates to a dynamic random access memory device and an inspection method thereof.

2. Description of Related Art

FIG. 1 illustrates an equivalent circuit of a memory cell of a dynamic random access memory (hereinafter abbreviated as “DRAM”). In FIG. 1, reference numeral 10 denotes a switch transistor of a memory cell or, in other words, a memory cell transistor. Memory cell transistor 10 includes four terminals, namely, word line 1a, bit line 1b, storage node 1c, and substrate terminal 1d, and one storage capacitor 20. In addition, storage capacitor 20 includes capacitor upper electrode 2.

Generally, memory cell transistor 10 is an N-channel MOS transistor that becomes active (selected state) when a “high” voltage is applied to word line 1a and inactive (unselected state) when a “low” voltage is applied to word line 1a. Information stored in the memory cell is read/written when the memory cell is active. In other words, when writing a logic “1” (hereinafter, this operation is to be referred to as “write”), a voltage corresponding to the logic “1” is applied to bit line 1b in a state where a “high” voltage is applied to word line 1a connected to a gate electrode of memory cell transistor 10. At this point, a current flows between a drain and a source of memory cell transistor 10, and storage capacitor 20 connected to storage node 1c is charged with a logic “1” voltage. Subsequently, memory cell transistor 10 is turned off when a “low” voltage is applied to word line 1 and storage capacitor 20 remains charged by the logic “1” voltage (hereinafter, this state is to be referred to as “pause”). When writing a logic “0”, a voltage corresponding to the logic “0” is applied to bit line 1b in an active state.

When reading such information (hereinafter, this operation is to be referred to as “read”), a “high” voltage is applied to word line 1a to extract a potential of storage capacitor 20 to bit line 1b through a drain-source path of memory cell transistor 10, whereby the signal is detected by a sense amplifier to determine “0” or “1”.

However, during a pause after the write“1” operation, a leakage current is generated due to a reverse bias created at a PN junction between storage node 1c and substrate terminal 1d. Since the leakage current causes loss over time of the accumulated charge, in order to retain data, data needs to be refreshed (repetitive operation of readout-rewrite) at a certain time interval.

Since the leakage current generated during a pause differs from one memory cell to another, data retention time also differs from cell to cell. Therefore, when shipping DRAM chips, data retention capabilities of all memory cells in the chip need to be tested so as to guarantee that the data retention times of all cells are equal to or greater than the refresh time interval. Data retention capability is normally evaluated by a test referred to as a pause-refresh test.

A pause-refresh test is performed according to an operation procedure for writing “1” to a tested memory cell, followed by a pause in a state where the transistor is turned off and a read operation performed. The pause duration is determined based on the refresh time interval. Normally, a pause-refresh test prior to shipment is performed either once or twice by varying test conditions such as voltage application patterns during a pause after write operation to cells other than a tested memory cell or during a pause time tPAUSE as illustrated in FIG. 2.

Data retention time has conventionally been considered to be a constant value unique to a memory cell. As such, it was thought that one test per one test condition as described above is sufficient to completely screen for retention faults. However, Non-Patent Document 1 (D. S. Yaney et al., 1987 IEDM Tech. Dig., pp. 336-339) and Non-Patent Document 2 (P. J. Restle et al., 1992 IEDM Tech. Dig., pp. 807-810) disclose that a phenomenon is observed in which data retention time fluctuates in a manner resembling random telegraph noise as illustrated in FIG. 3 in a small portion of the memory cells. A phenomenon in which data retention time varies over time in this manner is referred to as a variable retention time (VRT). As illustrated in FIG. 3, in a VRT phenomenon, a good state characterized by having long data retention time and a bad state characterized by having short data retention time are often alternately observed. In addition, the fluctuation may sometimes take the form of a binary fluctuation or a multivalued fluctuation greater than binary. Furthermore, durations of the respective states vary, making it difficult to predict when a fluctuation will occur. In a case of a memory cell indicating VRT, there is a concern that even when pre-shipment inspection results show that the DRAM is in a good state, in which the data retention time is long, the occurrence of a bad state after shipment, may result in decreased data retention time and may cause a retention fault. Hereinafter, a retention fault attributable to VRT is to be referred to as a VRT fault.

A VRT fault is a serious fault whose occurrence after delivery to a customer is a concern. The degree of seriousness of the fault is increasing in accordance with an increase in DRAM integration. This is because if the occurrence rate of VRT fault memory cells is constant, then the occurrence rate of VRT fault memory cells increases in proportion to DRAM integration. For example, when DRAM integration doubles, the probability of VRT fault memory cells included in a single chip also doubles. In the future, a test method capable of reliably screening for VRT faults is essential to further enhance DRAM integration.

For the VRT fault screening test method described above, JP2006-252648A discloses that it is effective to: repeatedly perform retention measurement; apply a high reverse bias or a hot-carrier stress between a storage node and a substrate of a memory cell transistor prior to each retention measurement; or apply a forward bias or create a field-off state prior to each retention measurement. However, merely repeating retention measurement cannot reliably screen for VRT fault memory cells whose retention capabilities may fluctuate at any time. In addition, although applying a high reverse bias or a hot-carrier stress to a PN junction between a storage node and a substrate increases the occurrence rate of VRT failures, degradation of device properties is also caused by high-field stress. Therefore, the test method can not be suitably performed on devices prior to shipment. Furthermore, applying a forward bias to a PN junction between a storage node and a substrate involves commonly applying a bias not used during normal operations on substrate terminals of devices in the chip, thus creating a concern that applying such a bias may degrade properties of devices other than the memory cell. Therefore, the use of either test method for pre-shipment inspection is problematic.

Moreover, recently, Non-Patent Document 3 (Y. Mori et al., 2005 IEDM Tech. Dig., pp. 1034-1037) has reported that a fluctuation over time of a junction leakage current generated between a drain and a substrate or, in other words, a fluctuation over time of one of the factors for determining retention time causes VRT. While VRT faults have been heretofore described using an example of a memory cell transistor of a typical DRAM as illustrated in FIG. 1, a VRT fault conceivably occurs in a similar manner in a new type of DRAM that is known as a Zero Capacitor-RAM (hereinafter referred to as a Z-RAM) such as illustrated in FIG. 4. Z-RAM records 0/1 by accumulating a charge on a transistor substrate portion instead of on a capacitor. In this case, in the same manner as the typical DRAM illustrated in FIG. 1, leakage of accumulated charge 30 occurs due to the generation of junction leakage current 31 between source 4 on insulator film 6 and a substrate or between drain 5 and the substrate. Therefore, VRT originating from a fluctuation in junction leakage current conceivably also occurs in Z-RAM. As seen, VRT is a universal fault that occurs not only in typical DRAMs but also in any memory device whose retention capability is dictated by a junction leakage current.

Consequently, for DRAMs whose retention capability is dictated by a junction leakage current, whether or not memory cells are normal or have faults, there is a need to establish a test method capable of reliably screening for VRT faults that cannot be screened by a conventional pause-refresh test in a short period of time without causing damage to the normal memory cells other than VRT fault memory cells or without causing damage to devices contained in the same chip.

### SUMMARY

The present invention seeks to solve one or more of the above problems, or to improve upon those problems at least in part.

In one embodiment, there is provided a method that applies a bias that accumulates holes on a gate electrode-side interface of a substrate to the gate electrode immediately prior to a pause-refresh test, and after applying the bias, performs a pause-refresh test to screen for VRT fault memory cells. While even performing the aforementioned test once is effective in screening for VRT faults, the screening rate can be further improved by repetitively performing the test a plurality of times.

According to the present invention, whether or not memory cells are normal or have faults, it is now possible to reliably screen VRT faults that cannot be screened by a conventional pause-refresh test in a short period of time without causing damage to the normal memory cells, or without causing damage to devices contained in the same chip.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a conceptual diagram of a memory cell of a DRAM;

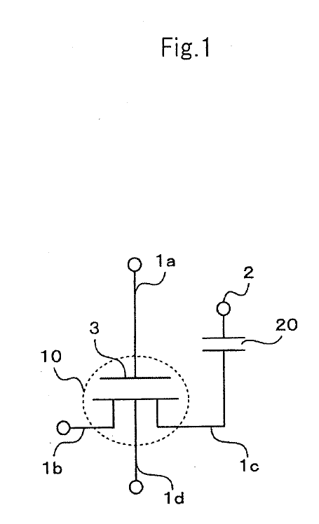

FIG. 2 is a conceptual diagram of a DRAM inspection method;

FIG. 3 is a conceptual diagram for describing a variable retention time phenomenon;

FIG. 4 is a conceptual diagram of a pause state after performing a write “1” to a Z (zero-capacitor)-RAM memory cell;

FIG. 5 is a conceptual diagram of a DRAM inspection method according to a first exemplary embodiment;

FIG. 6 is a conceptual diagram of a biased state during inspection of a DRAM according to the first exemplary embodiment;

FIG. 7 is a conceptual diagram of a flow of the application of a bias during inspection of a DRAM according to the first exemplary embodiment;

FIG. 8 is a diagram describing hole accumulation locations indicated in the first exemplary embodiment;

FIG. 9 is a conceptual diagram of a flow of the application of a bias during inspection of a DRAM according to the first exemplary embodiment;

FIG. 10 is a conceptual diagram of a flow of the application of a bias during inspection of a DRAM according to the first exemplary embodiment;

FIG. 11A is a conceptual diagram of a DRAM circuit according to the first exemplary embodiment;

FIG. 11B is an explanatory diagram of the vicinity of a VKK input terminal illustrated in FIG. 11A;

FIG. 12 is a conceptual diagram of a DRAM inspection method according to a second exemplary embodiment;

FIG. 13 is a conceptual diagram of a method of optimizing inspection conditions of a DRAM according to the second exemplary embodiment and a fourth exemplary embodiment;

FIG. 14 is a conceptual diagram of a DRAM inspection method according to a third exemplary embodiment;

FIG. 15 is a conceptual diagram of a biased state during inspection of a DRAM according to the third exemplary embodiment;

FIG. 16 is a conceptual diagram of a flow of the application of a bias during inspection of a DRAM according to the third exemplary embodiment;

FIG. 17 is a conceptual diagram of a biased state during a pause after executing a write “1” to a DRAM;

FIG. 18 is a conceptual diagram of the application of a bias flow during inspection of a DRAM according to the third exemplary embodiment; and

FIG. 19 is a conceptual diagram of a DRAM inspection method according to the fourth exemplary embodiment.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments that are illustrated for explanatory purposes.

In the following exemplary embodiments, screening of VRT faults is enabled by optimizing a voltage to be applied during a test and by optimizing procedures for the test, and a reduction of the test duration and simplification of the test are enabled by embedding test circuits such as a screening voltage generation circuit and a switching circuit that switches among the screening voltage generation circuit and normal operation circuits into a chip. All of the following exemplary embodiments assume a case where an NMOS is used as a memory cell transistor. When a PMOS is used as a memory cell transistor, a similar test can be applied with the sole exception of bias polarities inverted with respect to NMOS.

### First Exemplary Embodiment

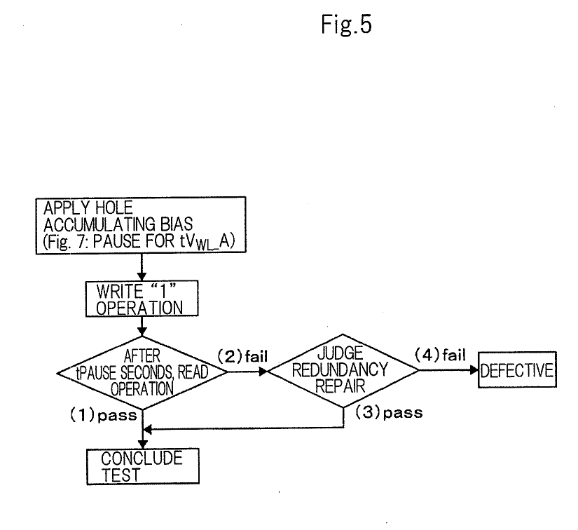

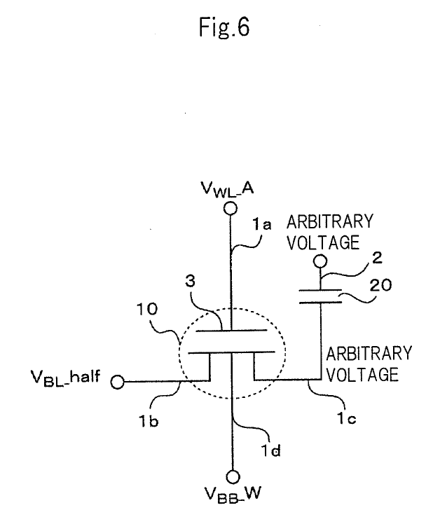

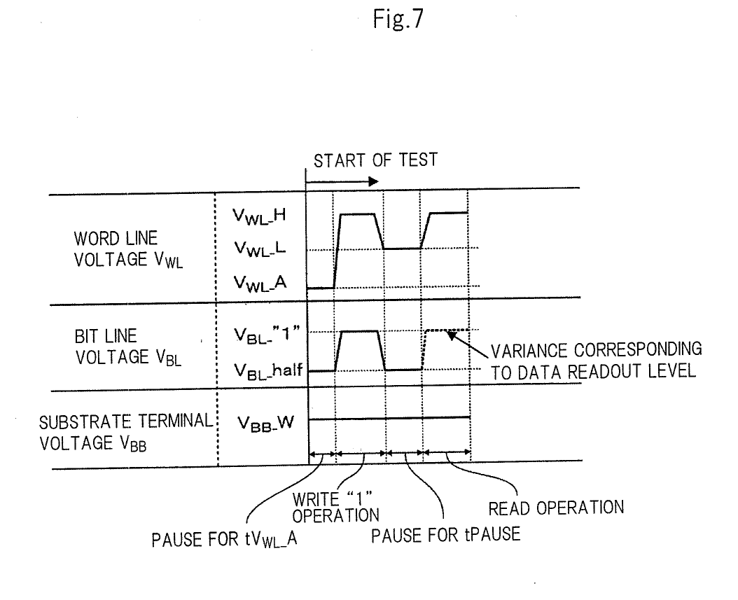

FIG. 5 illustrates a test procedure for screening VRT faults according to a first exemplary embodiment. FIGS. 6 and 7 illustrate details of bias conditions during a test. As illustrated in FIG. 5, the present test is a test method whose basic configuration involves starting the test by applying (FIG. 6) a bias, that accumulates holes on a gate electrode-side interface of a substrate, to the gate electrode, and immediately after applying the bias, performing procedures of an ordinary pause-refresh test, namely, performing a write “1” operation, pausing for tPAUSE seconds, and performing a read operation.

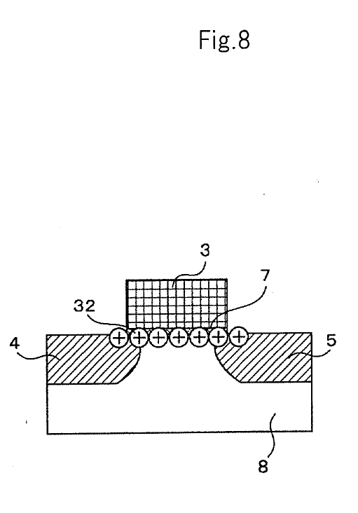

FIG. 8 is a schematic diagram for describing hole accumulation locations.

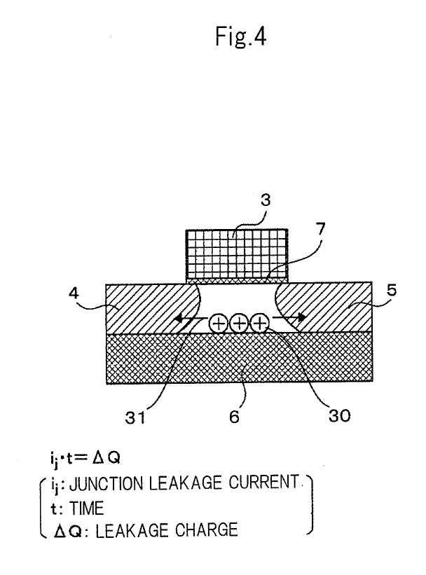

As illustrated in FIG. 8, holes 32 are accumulated on an interface on the side of gate electrode 3 of substrate 8. Note that in FIG. 8, like components to FIG. 4 will be denoted by like reference characters and descriptions thereof will be omitted.

For tPAUSE, a refresh time interval itself during the operation of a product, or a slightly longer time than the refresh time interval, is selected. A memory cell at which an error occurs during a read is judged to be a failed cell and a redundancy repair is attempted ((2) in FIG. 5). A chip in which an error occurs once again during the redundancy repair is judged to be defective ((4) in FIG. 5). When a read after a pause results in all memory cells passing the test ((1) in FIG. 5) or when a redundancy repair is successful even if an error has occurred ((3) in FIG. 5), the chip is judged to be faultless and the test is concluded.

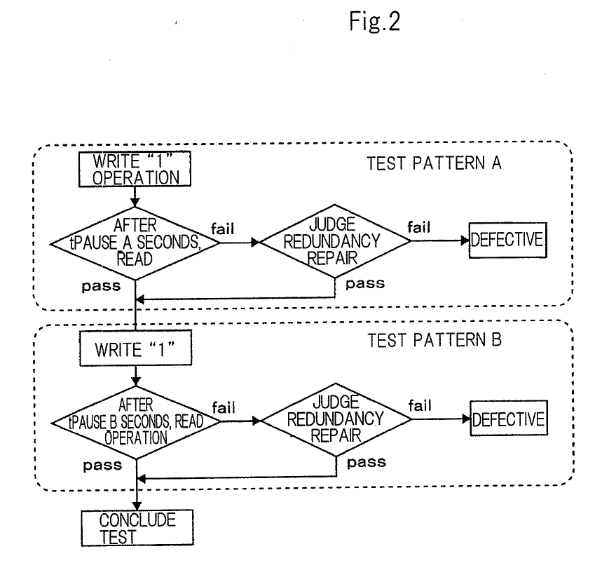

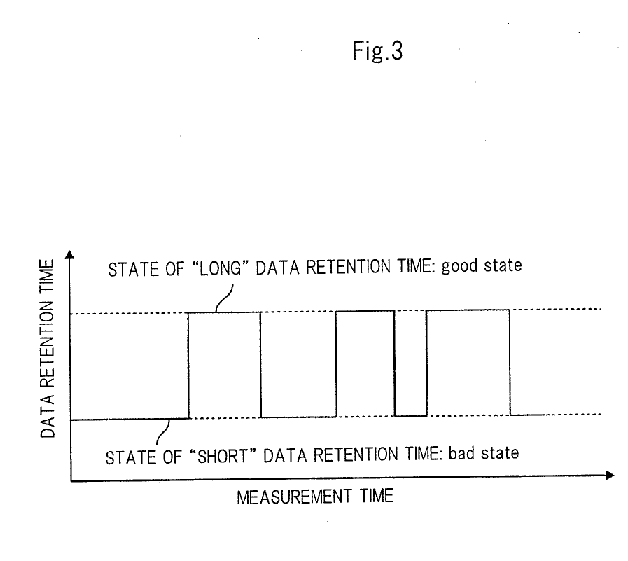

When a VRT fault memory cell indicating a variance in data retention time such as that illustrated in FIG. 3 is included in the tested chip, there is a possibility that the tested chip will not be screened as being defective even when performing the test illustrated in FIG. 2. In order to screen for a VRT fault memory cell having both long data retention times (good state) and short data retention times (bad state), the VRT fault memory cell is required to be in a bad state when a pause-refresh test is performed. A study of a bad state occurrence rate performed by varying bias conditions on several VRT fault memory cells as samples has revealed that the bad state occurrence rate is improved by applying a bias that accumulates holes 32 on a substrate interface under gate electrode 3 of memory cell transistor 10 to gate electrode 3, and subsequently by applying a normal pause bias. Therefore, a VRT fault screening effect can be expected even when performing the test illustrated in FIG. 5 once.

FIG. 7 illustrates an example of bias states at respective terminals when the hole accumulating bias illustrated in FIG. 5 is additionally applied immediately prior to a pause-refresh test. A bias application procedure of the present test is as described below.

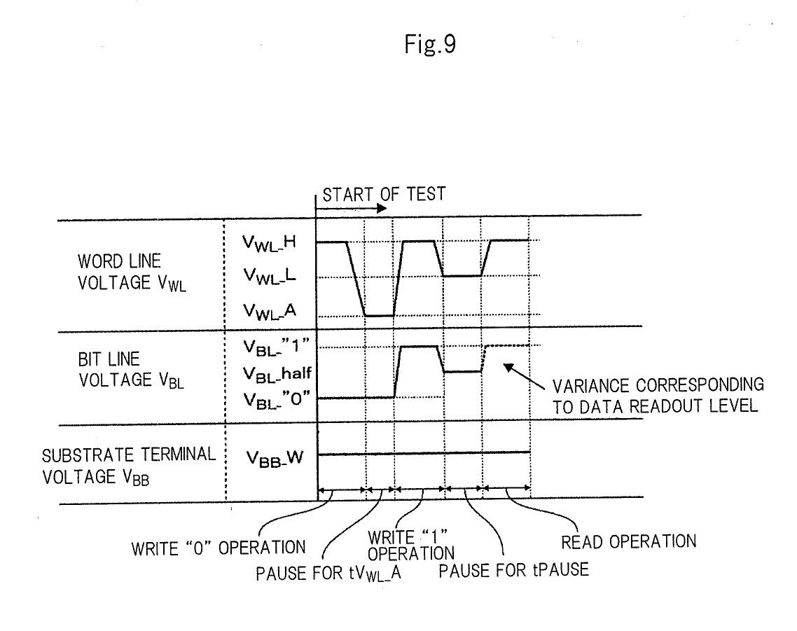

A write substrate terminal voltage V_{BB}_{_{—}}W is to be continuously applied to substrate terminal 1d during the duration of the present test. First, a bias V_{WL}_{_{—}}A that accumulates holes 32 on substrate face 8 under the gate electrode is applied to word line 1a for a time period tV_{WL}_{_{—}}A and holes 32 are accumulated on substrate face 8 under the gate electrode. At this point, the potential of bit line 1b is arbitrary, and a precharge voltage V_half having a value intermediate between a write “1” voltage V_{BL}_{_{—}}“1” and a write “0” voltage V_{BP}_{_{—}}“0” may be applied. In addition, the hole accumulating bias V_{WL}_{_{—}}A is to be selected from a range where holes 32 are accumulated on the substrate interface but a junction does not break down. Subsequently, a pause-refresh test is performed. In other words, as illustrated in FIG. 7, a write “1” operation, a pause for tPAUSE seconds, and a read operation are performed to evaluate the data retention capability of the tested memory cell. During the write “1” operation, a “high” voltage V_{WL}_{_{—}}H is applied to word line 1a and a write “1” voltage V_{BL}_{_{—}}“1” is applied to bit line 1b. In addition, during the pause, a “low” voltage V_{WL}_{_{—}}L is applied to word line 1a and an arbitrary voltage such as V_half is applied to bit line 1b. Finally, during the final read operation, a “high” voltage V_{WL}_{_{—}}H is applied to word line 1a and the variance of the potential of bit line 1b is read via a sense amplifier. As described earlier, in a pause-refresh test performed after applying such a hole accumulating bias, the bad state occurrence rate increases and VRT fault memory cells are more readily screened. Moreover, as illustrated in FIG. 9, the present test may alternatively be performed immediately prior to applying the hole accumulating bias and after performing a write “0” or a write “1” operation to stabilize the potential of storage node 1c.

In addition, as disclosed in Non-Patent Documents 1 and 2, VRT fluctuation tends to increase as the temperature rises. Therefore, VRT fault memory cells can be screened in a shorter period of time by performing the test illustrated in FIG. 5 at a temperature that is higher than a normal operating temperature.

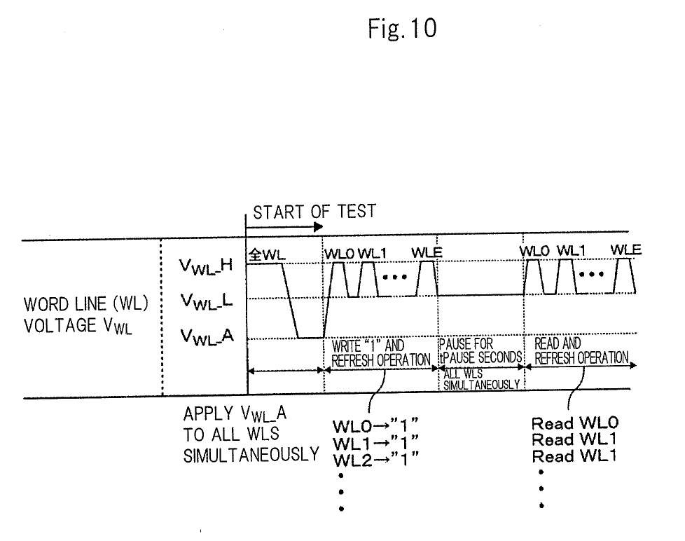

When applying the present test to all memory cells in a chip, the test duration can be reduced by simultaneously performing, in parallel, the application of voltage illustrated in FIG. 5 to a plurality of memory cells. For example, the test illustrated in FIG. 5 can be simultaneously performed in parallel on all of the memory cells in the chip or performed sequentially by dividing the memory cells into groups of several cells. In addition, as illustrated in FIG. 10, the memory cells may be divided for part of the processes of applying a hole accumulating bias, write, pause, and read operations illustrated in FIG. 5, and the remainder of the processes be performed simultaneously on all memory cells. In such a case, for the “write 1” operation illustrated in FIG. 10, respective word lines (WL0, WL1, . . . , WLE) are sequentially selected and a write operation is performed (after the write' operation, a refresh operation is continuously performed to maintain a storage state), and for the “read” operation, respective word lines (WL0, WL1, . . . , WLE) are sequentially selected and a read operation is performed (during the read operation, a refresh operation is continuously performed to maintain the storage state).

Moreover, the present test may be performed at any time. In other words, the present test may be performed in a wafer testing state, after division into individual chips, or after assembly into a package.

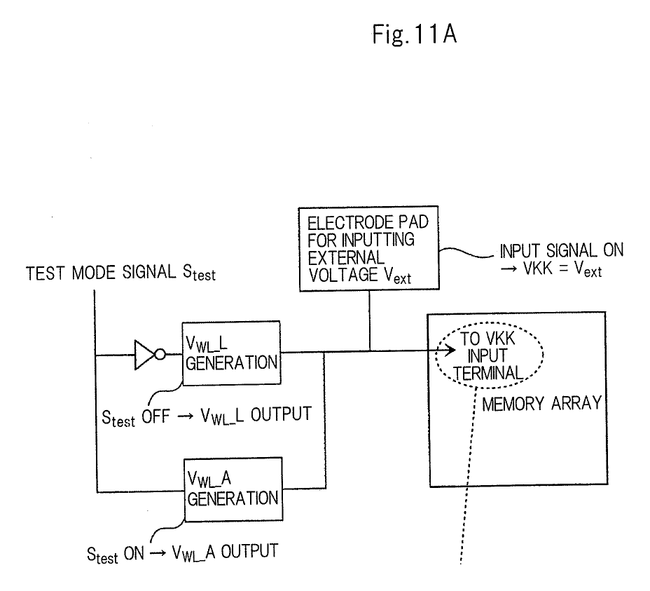

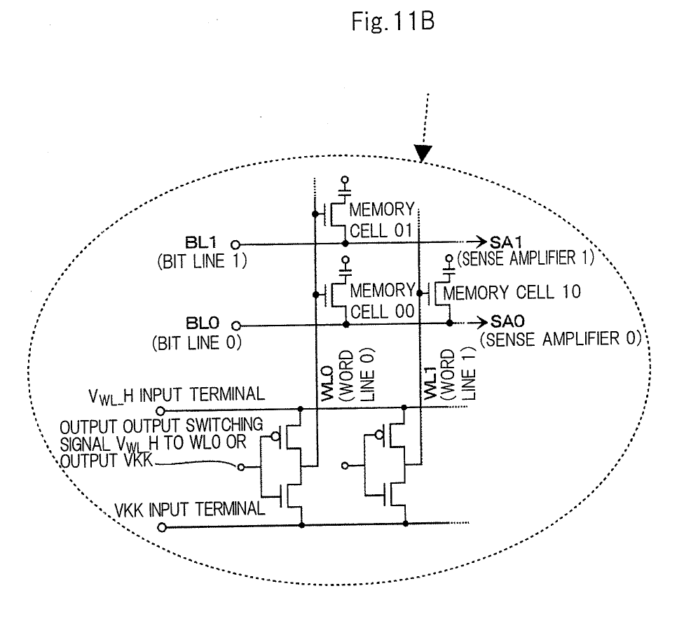

In addition, in the first exemplary embodiment, a bias not used in normal operations, namely, V_{WL}_{_{—}}A needs to be generated. Therefore, during circuit design, for example, as illustrated in FIG. 11, wiring for applying V_{WL}_{_{—}}A from the outside of the chip and an electrode pad connected to the wiring are to be provided on a wafer, and a test circuit for generating V_{WL}_{_{—}}A is to be provided inside the chip. When performing the test according to the first exemplary embodiment in a wafer state, the test is executed by externally applying V_{WL}_{_{—}}A via the V_{WL}_{_{—}}A application electrode pad. When performing the test in an assembled state in a package, a test mode signal Sₜₑₛₜ is inputted and the V_{WL}_{_{—}}A generating test circuit is operated in test mode. In addition, a switching circuit switches between the V_{WL}_{_{—}}A generating test circuit and a pause-refresh test circuit for inspecting a data retention capability of a memory cell. The test according to the first exemplary embodiment is executed by an inspecting section including the V_{WL}_{_{—}}A generating test circuit, the pause-refresh test circuit, and the switching circuit. Moreover, depending on the execution timing or manner of executing the test, only circuits for externally applying or only a V_{WL}_{_{—}}A generating test circuit may be provided.

### Second Exemplary Embodiment

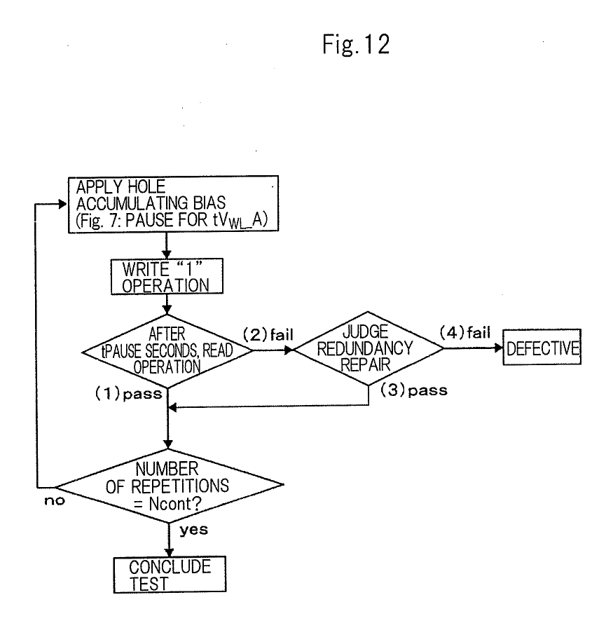

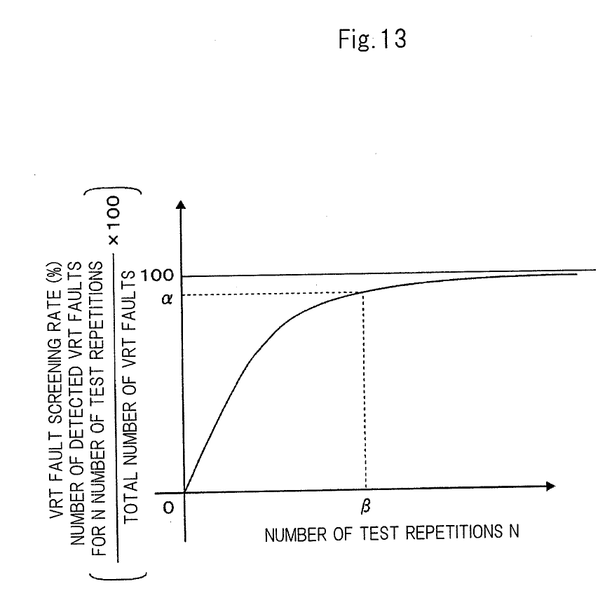

FIG. 12 illustrates a test procedure for screening VRT faults according to a second exemplary embodiment. A feature of the present test is that the test illustrated in FIG. 5 is repeated an optimized number of times (Ncont). As illustrated in FIG. 13, a VRT fault screening rate is improved by repetitively performing the test illustrated in FIG. 5. In this case, the VRT fault screening rate is defined as follows. The number of detected VRT faults tends to saturate when the test illustrated in FIG. 5 is repeated a certain number of times or more. The VRT fault screening rate illustrated in FIG. 13 is obtained, on the assumption that the saturated value is the total number of VRT faults, by calculating a proportion of the number of detections for N number of repetitions with respect to the total number of VRT faults. Using FIG. 13, the number of test repetitions β with respect to a target screening rate a can be obtained as an optimum number of screening test repetitions Ncont (FIG. 12).

While the greater the number of test repetitions, the better the screening rate, test duration is ideally minimized since an increase in test duration leads to an increase in manufacturing cost. Therefore, determining a target screening rate and obtaining an optimum value of the number of test repetitions, as described above, is an important procedure from the perspective of cost reduction and reliability enhancement.

### Third Exemplary Embodiment

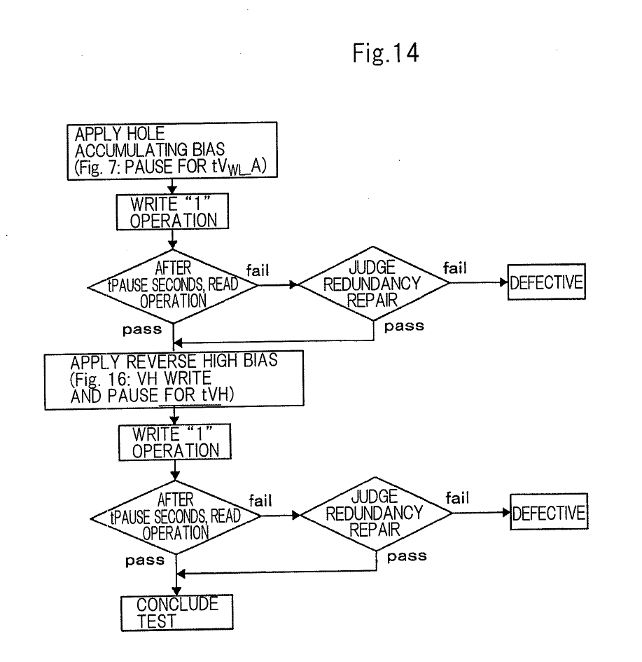

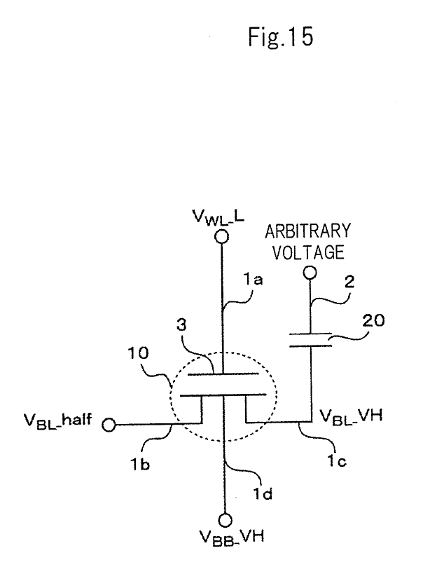

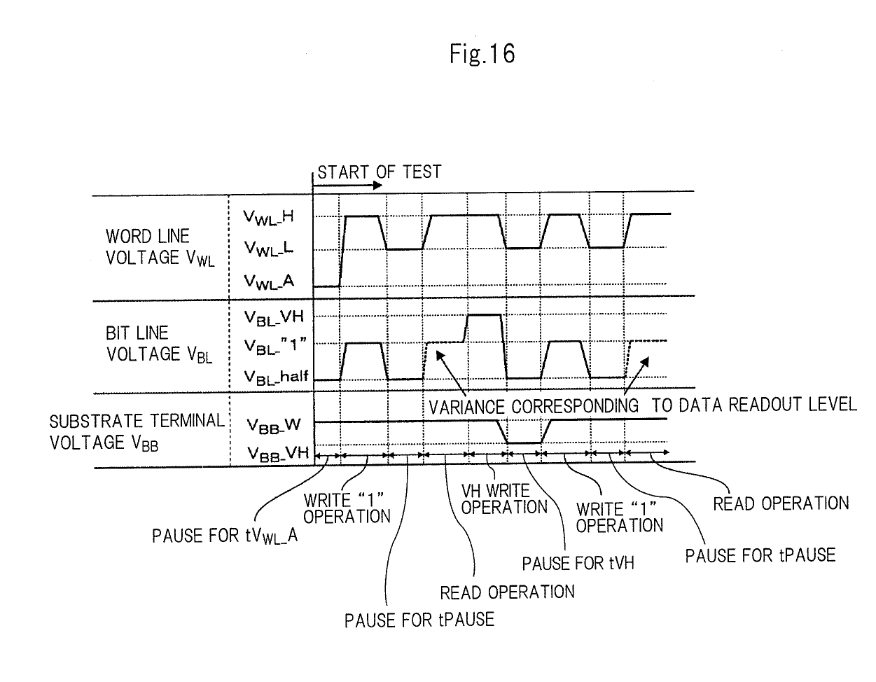

FIG. 14 illustrates a test procedure for screening VRT faults according to a third exemplary embodiment. FIGS. 15 and 16 illustrate details of bias conditions during a test. A feature of the present test (FIG. 14) is that a reverse bias that is higher than pause bias conditions is applied (FIG. 15) between storage node 1c and substrate terminal 1d that are included in memory cell transistor 10 before or after the test described in the first exemplary embodiment is performed, and a pause-refresh test is performed immediately after applying the reverse bias. In FIG. 14, a hole accumulating bias is applied before a first pause-refresh test and a reverse high bias is applied immediately before a second pause-refresh test. However, the same effect can be achieved by a reverse sequence or, in other words, by applying the reverse high bias immediately before the first pause-refresh test and the hole accumulating bias immediately before the second pause-refresh test. As will be described later, according to the present exemplary embodiment, VRT faults can be screened in a shorter period of time and with higher reliability as compared to the first exemplary embodiment.

In order to reduce the time required by VRT fault screening, VRT faults need to be exposed at a faster rate or, in other words, a bad state occurrence rate per unit time needs to be increased.

A study of a bad state occurrence rate using several VRT fault memory cells as samples has revealed that in a portion of the memory cells, the higher the reverse bias, the higher the bad state occurrence rate. The degree of variation due to the bias differed from sample to sample.

In addition, it was observed that the occurrence of a bad state, when a bias that is higher or lower than during a write “1” operation is applied, continues for a certain amount of time even when a write “1” bias is subsequently applied. Consequently, a severalfold increase in VRT fault detection frequency was confirmed by adding a reverse high bias-applied pause-refresh test before or after the test described in the first exemplary embodiment in comparison to a case where the reverse high bias-applied pause-refresh test is not added.

FIG. 16 illustrates an example of bias states at respective terminals in a case where a hole accumulating bias is applied immediately before a first pause-refresh test and a reverse high bias is applied immediately before a second pause-refresh test as illustrated in FIG. 14. A bias application procedure of the present test is as described below.

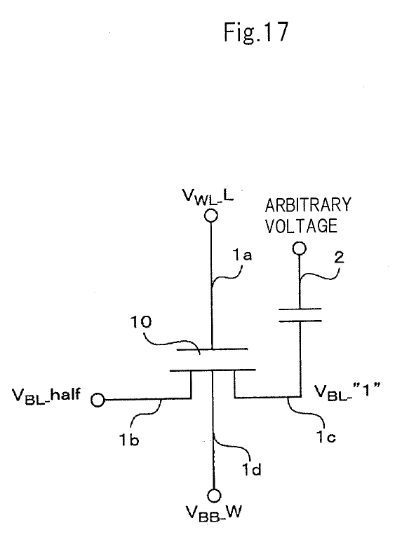

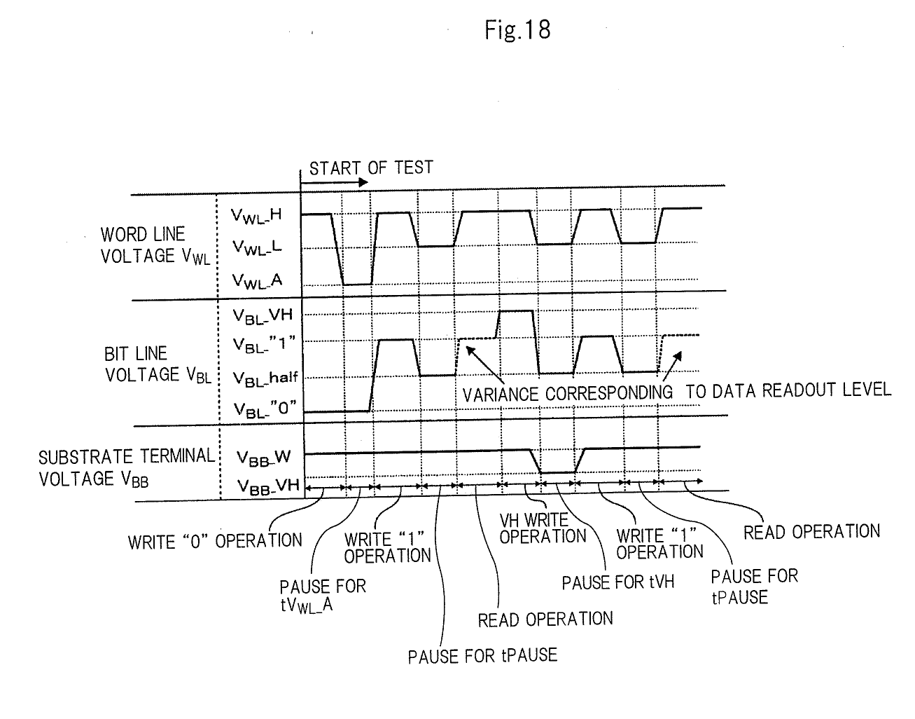

First, the hole accumulating bias is applied by the same procedure as described earlier with reference to FIG. 7. Next, when applying the reverse bias, a “high” voltage V_{WL}_{_{—}}H is applied to word line 1a, a voltage V_{BL}_{_{—}}VH that is higher than a write “1” voltage V_{BL}_{_{—}}“1” is applied to bit line 1b, and a write substrate terminal voltage V_{BB}_{_{—}}W is applied to substrate terminal 1d at basically the same time, and storage capacitor 20 connected to the side of storage node 1c is charged by voltage V_{BL}_{_{—}}VH. Subsequently, a pause period of tVH seconds (during which a reverse high field is generated between the storage node and the substrate) is implemented in a state where a “low” voltage V_{WL}_{_{—}}L is applied to word line 1a and a voltage V_{BB}_{_{—}}VH that is negatively greater than V_{BB}_{_{—}}W is applied to substrate terminal 1d. The potential of bit line 1b is arbitrary, and a voltage V_half having a value intermediate between the write “1” voltage V_{BL}_{_{—}}“1” and a write “0” voltage V_{BL}_{_{—}}“0” may be applied as illustrated in FIG. 16. At this point, the memory cell transistor is turned off and a reverse bias whose magnitude is approximately determined by (V_{BL}_{_{—}}VH−V_{BB}_{_{—}}VH) is generated at a PN junction between storage node 1c and the substrate (FIG. 15). The bias generated at this point is greater than a bias generated during the pause (FIG. 17) after the write “1” operation. A pause-refresh test is performed after generating such a high bias at a storage node-side PN junction. In other words, as illustrated in FIG. 16, after a pause of tVH seconds, a write “1” operation, a pause for tPAUSE seconds, and a read operation are performed to evaluate the data retention capability of the tested memory cell. As described earlier, in a pause-refresh test performed after applying such a high bias, VRT faults that are likely to increase a bad state occurrence rate due to the application of the high bias are more readily screened. Moreover, as illustrated in FIG. 18, the present test may alternatively be performed immediately prior to applying the hole accumulating bias and after performing a write “0” operation or a write “1” operation to stabilize the potential of storage node 1c.

In addition, as disclosed in Non-Patent Documents 1 and 2, VRT fluctuation tends to increase as the temperature rises. Therefore, VRT fault screening probability is increased by performing the test illustrated in FIG. 14 at a temperature that is higher than a normal operating temperature.

When applying the present test to all memory cells in a chip, the test duration can be reduced by simultaneously performing, in parallel, the voltage application illustrated in FIG. 14 on a plurality of memory cells. For example, the test illustrated in FIG. 14 can be simultaneously performed in parallel on all of the memory cells in the chip or performed sequentially by dividing the memory cells into groups of several cells. In addition, the memory cells may be divided for part of the processes of applying hole accumulating bias, write, pause, and read operation illustrated in FIG. 14, and the remainder of the processes be performed simultaneously on all memory cells.

Moreover, the present test may be performed at any time. In other words, the present test may be performed in a wafer testing state, after division into individual chips, or after assembly into a package.

In addition, when using the present test for screening prior to product shipment, the present test needs to be prevented from causing deterioration of normal memory cells other than VRT fault memory cells. As such, the bias condition for the reverse high bias application process is to be determined in a range where such deterioration of normal memory cells does not occur.

In addition, in the third exemplary embodiment, biases not used in normal operations, namely, V_{WL}_{_{—}}A and V_{BB}_{_{—}}VH need to be generated. Therefore, during circuit design, in the same manner as illustrated in FIG. 11, wiring for applying V_{WL}_{_{—}}A and V_{BB}_{_{—}}VH from outside of the chip and an electrode pad connected to the wiring are to be provided on a wafer, and a test circuit for generating V_{WL}_{_{—}}A and V_{BB}_{_{—}}VH is to be provided inside the chip. When performing the test according to the third exemplary embodiment in a wafer state, the test is executed by externally applying V_{WL}_{_{—}}A and V_{BB}_{_{—}}VH via the electrode pad for applying V_{WL}_{_{—}}A and V_{BB}_{_{—}}VH. When performing the test in an assembled state in a package, the test according to the third exemplary embodiment is executed by operating a test circuit for generating V_{WL}_{_{—}}A and V_{BB}_{_{—}}VH in a test mode. Moreover, depending on an execution timing or the manner of executing the test, only circuits for externally applying V_{WL}_{_{—}}A and V_{BB}_{_{—}}VH or only a test circuit for generating V_{WL}_{_{—}}A and V_{BB}_{_{—}}VH may be provided.

### Fourth Exemplary Embodiment

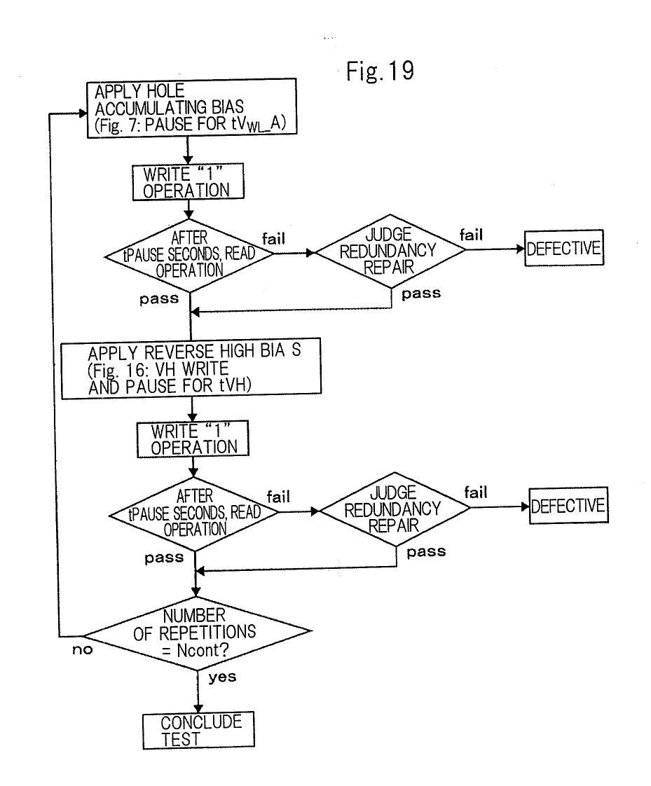

FIG. 19 illustrates a test procedure for screening VRT faults according to a fourth exemplary embodiment. A feature of the present test is that the test illustrated in FIG. 14 is repeated an optimized number of times (Ncont). As illustrated in FIG. 13, a VRT fault screening rate is improved by repetitively performing the test illustrated in FIG. 14. In this case, the VRT fault screening rate is defined as follows. The number of detected VRT faults tends to saturate when the test illustrated in FIG. 14 is repeated a certain number of times or more. The VRT fault screening rate illustrated in FIG. 13 is obtained on the assumption that the saturated value is the total number of VRT faults by calculating a proportion of the number of detections for N number of repetitions with respect to the total number of VRT faults. Using FIG. 13, the number of test repetitions a with respect to a target screening rate β can be obtained as an optimum number of screening test repetitions Ncont (FIG. 19).

While the greater the number of test repetitions, the better the screening rate, test duration is ideally minimized since an increase in test duration leads to an increase in manufacturing cost. Therefore, determining a target screening rate and obtaining the optimum value of the number of test repetitions as described above is an important procedure from the perspective of cost reduction and reliability enhancement.

It is apparent that the present invention is not limited to the above embodiments, but may be modified and changed without departing from the scope and spirit of the invention.

What is claimed is:

1. An inspection method of a dynamic random access memory device mounted with a plurality of memory cells having data retention capabilities,
the memory cells including a substrate, a source-drain region provided in a vicinity of a surface of the substrate, and a gate formed by laminating a gate insulator film provided on the surface of the substrate so as to cover an end of the source-drain region and a gate electrode, the inspection method comprising:
applying a bias to the gate electrode so that a hole is accumulated on an interface on the side of the gate electrode in a vicinity of an interface between the gate and the substrate and in a region where the gate and the substrate face each other, and performing a pause-refresh test for inspecting the data retention capability after applying the bias; and
screening a memory cell potentially including a retention fault attributable to a random change over time of the data retention capability from among the plurality of memory cells.

2. The inspection method of a dynamic random access memory device according to claim 1, wherein when applying the bias and subsequently performing the pause-refresh test, a series of operations involving applying the bias to the gate electrode before the pause-refresh test and subsequently performing the pause-refresh test is repeatedly performed N number of times, where the number N is determined corresponding to a preset fault screening rate.

3. The inspection method of a dynamic random access memory device according to claim 1, wherein
applying the bias and subsequently performing the pause-refresh test includes:
performing the pause-refresh test twice;
applying a bias to the gate electrode so that a hole is accumulated on an interface on the gate electrode side of the substrate that is a component of the memory cell before performing any one of the two pause-refresh tests; and
applying a reverse bias having a higher voltage than a voltage applied during an operation of the dynamic random access memory device between a source-drain region connected to a storage node that is a component of the memory cell and the substrate before performing the other of the two pause-refresh tests.

4. The inspection method of a dynamic random access memory device according to claim 3, wherein performing the pause-refresh test twice, applying the hole accumulating bias, and applying the reverse high bias are repeatedly performed N number of times, where the number N is determined corresponding to a preset fault screening rate.

5. A dynamic random access memory device mounted with a plurality of memory cells having data retention capabilities, the dynamic random access memory device comprising
an inspecting section that executes an inspection of the dynamic random access memory device, wherein
the memory cells include a substrate, a source-drain region provided in a vicinity of a surface of the substrate, and a gate formed by laminating a gate insulator film provided on the surface of the substrate so as to cover an end of the source-drain region and a gate electrode, and
the inspecting section includes:
a test circuit for applying, to the gate electrode, a bias such that a hole is accumulated on an interface on the side of the gate electrode in a vicinity of an interface between the gate and the substrate and in a region where the gate and the substrate face each other;
a pause-refresh test circuit for inspecting the data retention capability, and
a switching circuit that switches between the test circuit and the pause-refresh test circuit.

6. The dynamic random access memory device according to claim 5, wherein the memory cells include Z-RAMs.
